(19) United States
(12) Patent Application Publication
(10) Pub. No.: US 2011/0157560 A1
(43) Pub. Date: Jun. 30, 2011

(54) ELECTRONIC APPARATUS AND PROJECTOR

(75) Inventor: Chi-Hung Hsiao, Taipei County (TW)

(73) Assignee: QISDA CORPORATION, Taoyuan County (TW)

(21) Appl. No.: 12/980,448

(22) Filed: Dec. 29, 2010

(30) Foreign Application Priority Data
Dec. 30, 2009 (TW) 098145781

(51) Int. Cl. G03B 21/16; H05K 7/20

(52) U.S. Cl. 353/58; 361/695; 353/61

(57) ABSTRACT

The invention discloses an electronic apparatus and a projector by use of two passages formed in a casing for two air-flows passing through, each of which is generated by at least fan. Heat-dissipation devices are disposed in the passages substantially evenly so as to dissipate the heat generated in operation by an optical module disposed in the casing by the air-flows. The purpose of efficient usage of the apparatus space is therefore achieved. For the basis of special heat-dissipation requirement and assembly design, one of the fans is disposed between two of the heat-dissipation devices so that the two heat-dissipation devices could obtain better heat-dissipation efficiency; further, there could be an open space disposed between two of the heat-dissipation devices and adjacent to a light source of the optical module for the installation of the light source and the following installation of the fan, so that the whole volume of the electronic apparatus or the projector could be further reduced.

### BACKGROUND OF THE INVENTION

1. Field of the Invention

The present invention relates to an electronic apparatus and a projector having a suitable heat-dissipation fan configuration to obtain good heat-dissipation efficiency.

2. Description of the Prior Art

With the development of the electronic technology, various electronic products are used in our daily life. Most electronic products have heat dissipation issues. Poor heat dissipation not only shortens the life of the electronic components in the electronic product, but also directly affects the performance of the electronic product. For example, when a projector has poor heat dissipation performance, the temperature of the light source of the projector will become very high. If a lamp is used as light source, the lamp will be burned; if a LED is used as light source, the light emitting efficiency of the LED will be poor, and the color performance of the image projected by the projector will be also poor.

Recently, all kinds of consumer electronic products are designed to become smaller and thinner. Although this design enhances the affinity of electronic products to the users, it also makes the above-mentioned heat dissipation issues become more serious. The current heat dissipation solutions are to use the low heat-emission electronic components, or to use the fan to guide the air-flow to dissipate the heat generated by the electronic components. Although using the low heat-emission electronic components can reduce the heat generated in the electronic product, the air-flow heat dissipation method is also needed to dissipate the heat. In the fan guiding air-flow heat dissipation solutions, how to dispose the fans to guide the air-flow to reach better heat dissipation efficiency will be a key point.

However, under the design requirements of small size and thin thickness, how to design suitable air-flow paths in the definite space of the electronic product to reach good heat dissipation efficiency will be an important issue needed to be overcome.

### SUMMARY OF THE INVENTION

A scope of the invention is to provide an electronic apparatus having suitable fan configuration to reach good heat dissipation efficiency.

The electronic apparatus of the invention includes a casing, an optical module, a first heat-dissipation device, a second heat-dissipation device, and a first fan. The casing includes a first air-inlet and a first air-outlet, wherein a first passage is formed between the first air-inlet and the first air-outlet. The optical module is disposed in the casing; the optical module has a first light source and a second light source. The first heat-dissipation device is disposed on the first passage and connected to the first light source. The second heat-dissipation device is disposed on the first passage and connected to the second light source. The first fan is disposed between the first heat-dissipation device and the second heat-dissipation device on the first passage. The first fan generates a first air-flow passing through the first heat-dissipation device and the second heat-dissipation device. By doing so, the first heat-dissipation device and the second heat-dissipation device disposed at two sides of the first fan can obtain good heat dissipation efficiency.

In addition, the casing further includes a second air-inlet and a second air-outlet, and a second passage is formed between the second air-inlet and the second air-outlet, the optical module comprises a third light source, the electronic apparatus further includes a third heat-dissipation device and a second fan. The third heat-dissipation device is disposed on the second passage and connected to the third light source. The second fan is disposed on the second passage, and the second fan generates a second air-flow passing through the third heat-dissipation device, wherein the first passage and the second passage are substantially parallel. In practical applications, the first passage and the second passage can be designed as a straight passage respectively. With the suitable configurations of the first passage and the second passage, the first air-flow and the second air-flow can pass around the inside of the casing, so that the heat generated by the electronic components disposed in the casing can be fully dissipated.

Another scope of the invention is to provide a projector having suitable fan configuration to reach good heat dissipation efficiency, so that the temperature of the light source will be well-controlled to reach good projection color performance.

The projector of the invention includes a casing, an optical module, a first heat-dissipation device, a second heat-dissipation device, a first fan, and a second fan. The casing includes a first air-inlet, a second air-inlet, a first air-outlet, and a second air-outlet, wherein a first passage is formed between the first air-inlet and the first air-outlet, a second passage is formed between the second air-inlet and the second air-outlet. The optical module is disposed in the casing, and the optical module has a first light source and a second light source. The first heat-dissipation device is disposed on the first passage and connected to the first light source. The second heat-dissipation device is disposed on the second passage and connected to the second light source. The first fan is disposed on the first passage, and the first fan generates a first air-flow passing through the first heat-dissipation device. The second fan is disposed on the second passage, and the second fan generates a second air-flow passing through the second heat-dissipation device.

In addition, the projector further includes a third heat-dissipation device, and the optical module includes a third light source, the third heat-dissipation device is disposed on the first passage and connected to the third light source. Therefore, the first air-flow also passes through the third heat-dissipation device. By doing so, the heat of the three light sources of the projector can be effectively dissipated by the three heat-dissipation devices, so that the temperature of the light source can be controlled, and the projector can be operated under normal light emitting efficiency.

Similarly, with the suitable configurations of the first passage and the second passage, the first air-flow and the second air-flow can pass through the inside of the casing, so that the heat of the electronic components in the casing can be fully dissipated.

Another scope of the invention is to provide a projector having suitable fan configuration to reach good heat dissipation efficiency, so that the temperature of the light source will be well-controlled and the stability that the optical module providing lights will be also increased to reach good projection color performance.

The projector of the invention includes a casing, an optical module, a first heat-dissipation device, and a first fan. The casing includes a first air-inlet and a first air-outlet, wherein a first passage is formed between the first air-inlet and the first air-outlet. The optical module is disposed on the first passage, and the optical module has a first light source. The first heat-dissipation device is disposed on the first passage and connected to the first light source. The first fan is disposed on the first passage, and the first fan generates a first air-flow passing through the first heat-dissipation device and the optical module. By doing so, the optical module can dissipate heat via the first air-flow, not only the temperature of the light source can be controlled, the deformation of the light coupling component (e.g., a prism) of the optical module can be also reduced, so that the light-emission stability of the optical module will be enhanced.

Compared to the prior arts, the electronic apparatus and the projector of the invention have suitable fan configurations to reach good heat dissipation efficiency for the electronic components disposed in the casing, so that the temperature of the light source will be well-controlled and the stability that the optical module providing lights will be also increased to reach good projection color performance. Furthermore, the entire volume of the electronic apparatus and the projector can be further reduced to meet the requirements of small size and thickness.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 illustrates a schematic diagram of an electronic apparatus in an embodiment of the invention.

FIG. 2 illustrates a schematic diagram of an electronic apparatus in another embodiment of the invention.

### DETAILED DESCRIPTION OF THE INVENTION

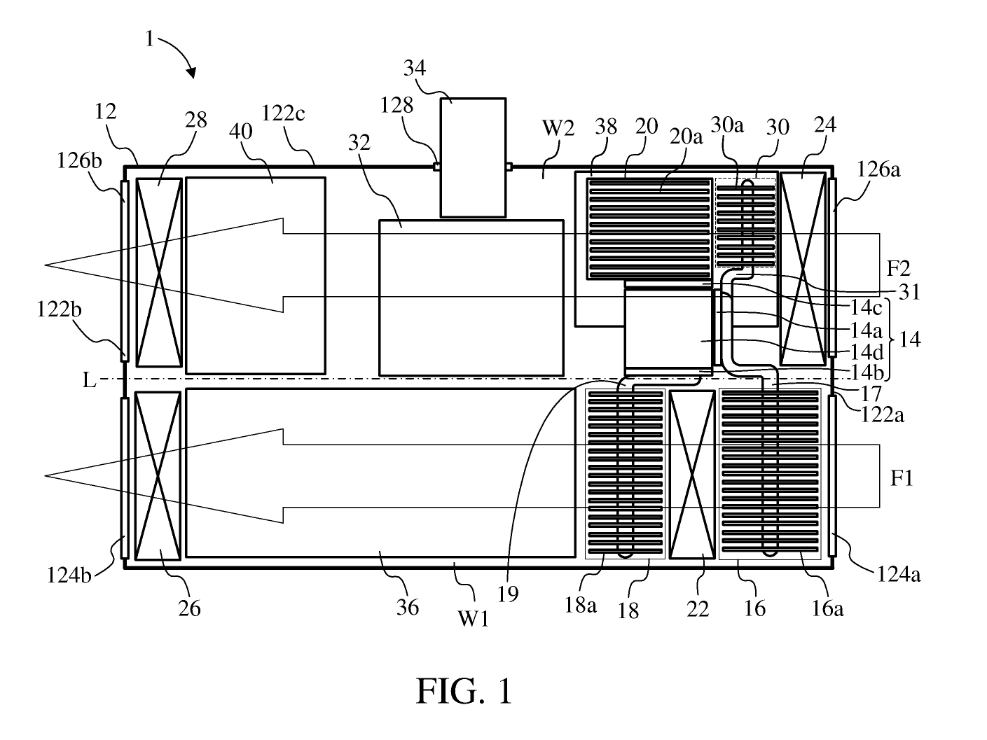

Please refer to FIG. 1. FIG. 1 illustrates a schematic diagram of an electronic apparatus in an embodiment of the invention. In this embodiment, the electronic apparatus is a projector 1, but not limited to this case. The projector 1 includes a casing 12, an optical module 14, three heat-dissipation devices 16 (marked by a dotted line), 18 (marked by a dotted line), and 20, and two fans 22 and 24.

The casing 12 has three sides 122a, 122b, and 122c. The side 122c is adjacent to the sides 122a and 122b respectively; the sides 122a and 122b are oppositely disposed. In the casing 12, the side 122a has two air-inlets 124a and 126a, and the side 122b has two air-outlets 124b and 126b. A passage W1 is formed between the air-inlet 124a and the air-outlet 124b, and an air-flow F1 generated by the fan 22 can pass through the passage W1 (marked by a thin solid line arrow box); another passage W2 is formed between the air-inlet 126a and the air-outlet 126b, and an air-flow F2 generated by the fan 24 can pass through the passage W2 (marked by a thin solid line arrow box). Wherein, according to the embodiment, the range of the passage W1 is about the bottom half of the casing 12 shown in FIG. 1, and the range of the passage W2 is about the upper half of the casing 12 shown in FIG. 1. And, the passage W1 and the passage W2 are separated by a chain line L. In other words, the inner space of the casing 12 is substantially covered by the two passages W1 and W2, therefore, all electronic components disposed in the casing 12 can obtain the heat-dissipation effect of the air-flows F1 and F2. However, the invention is not limited by the above-mentioned passage configurations. In addition, according to the configurations of the components in the embodiment, the passages W1 and W2 are both straight line passages and substantially parallel to each other, but not limited by this case.

The optical module 14 is disposed in the casing 12 and also on the passage W1; the optical module 14 also has three light sources 14a, 14b, 14c, and an optical coupling device 14d. The heat-dissipation device 16 is disposed on the passage W1 and connected to the light source 14a; the heat-dissipation device 18 is disposed on the passage W1 and connected to the light source 14b; the heat-dissipation device 20 is disposed on the passage W2 and connected to the light source 14c. According to the embodiment, the light source 14a is guided by a heat pipe 17 to connect to the heat-dissipation device 16; the light source 14b is guided by a heat pipe 19 to connect to the heat-dissipation device 18; the light source 14c is directly connected to the heat-dissipation device 20. For example, the heat-dissipation device 20 includes a heat conductive base connected to the light source 14c and the fins extended from the heat conductive base, and the heat conductive base itself can be a vapor chamber. Of course, the light source 14c can also connect to the heat-dissipation device 20 via a heat pipe. In other words, the invention is not limited by the above-mentioned connecting ways, any connecting way providing heat transferring and dissipating functions can be also used in the invention.

The fan 22 is disposed on the passage W1 and between the heat-dissipation devices 16 and 18, therefore, the air-flow F1 generated by the fan 22 will pass through the heat-dissipation devices 16 and 18 to directly dissipate the heat generated by the heat-dissipation devices 16 and 18, and indirectly dissipate the heat generated by the light sources 14a and 14b. The fan 24 is disposed on the passage W2, therefore, the air-flow F2 generated by the fan 24 will pass through the heat-dissipation devices 20 to directly dissipate the heat generated by the heat-dissipation device 20, and indirectly dissipate the heat generated by the light source 14c.

According to the embodiment, the casing 12 also includes two fans 26 and 28. The fans 26 and 22 will guide the air-flow F1 together to make the air-flow F1 have more stable flowing rate and heat-dissipation efficiency. If the fan 26 is disposed adjacent to the air-outlet 124b, the above-mentioned stability will be enhanced. Similarly, the fans 28 and 24 guide the air-flow F2 together, to make the air-flow F2 have more stable flowing rate and heat-dissipation efficiency. If the fan 28 is disposed adjacent to the air-outlet 126b, the above-mentioned stability will be enhanced.

In addition, the fan 24 is disposed adjacent to air-inlet 126a to enforce the air-flow F2 to flow into the passage W2, and the air-flow F2 is enforced to flow out of the passage W2 by the fan 28. In the embodiment, the passages W1 and W2 are substantially parallel as a straight line, so that the stable air-flows F1 and F2 can be formed. Although the fan 22 is not directly attached to the air-inlet 124a, since the heat-dissipation device 16 is disposed directly adjacent to the air-inlet 124a, and the fan 22 is disposed adjacent to the heat-dissipation device 16, after the air-flow F1 enters into the air-inlet 124a and passes through the heat-dissipation device 16, the air-flow F1 will be enforced by the fan 22 to flow. If the heat-dissipation device 16 is formed by fins parallel to the flowing direction of the air-flow F1, the fins can also guide air-flow to enforce the effect of guiding the air-flow F1 performed by the fan 22, and the guiding effect will not be reduced because the fan 22 is not directly attached to the air-inlet 124a.

It should be further mentioned that in the embodiment, the inner space of the casing 12 is roughly covered by the passages W1 and W2, therefore, the heat generated by the electronic components disposed in the casing 12 can be dissipated by the air-flows F1 and F2, and the passages W1 and W2 are both straight line passages and parallel to each other. Therefore, the turbulence of the air-flows will be largely reduced, so that the air-flows F1 and F2 can flow more smoothly.

In addition, in the embodiment, the heat-dissipation devices 16, 18, and 20 include a plurality of fins 16a, 18a, and 20a, and the length directions of the heat-dissipation devices 16 and 18 are substantially parallel to the flowing directions of the air-flow F1 and F2. In other words, the fins 16a, 18a, and 20a have effect of guiding air-flow at the same time, so that the turbulence of the air-flows will be largely reduced, so that the air-flows F1 and F2 can flow more smoothly.

According to the embodiment, the projector 1 also includes an optical engine 32, a camera lens 34, a power supply modules 36, 40, and a driving module 38. The optical engine 32 is disposed opposite to the optical module 14 between the heat-dissipation device 20 and the air-outlet 126b. The driving module 38 is disposed below the heat-dissipation device 20 (it can be disposed beyond the heat-dissipation device 20); so that the air-flow F2 can dissipate the heat generated by the driving module 38 and the heat-dissipation device 20 at the same time. The driving module 38 is used to drive the light sources 14a, 14b, 14c to emit lights and other electronic components to operate. The side 12c of the casing 12 also has an opening 128, the camera lens 34 is disposed on the opening 128 opposite to the optical engine 32. The optical coupling device 14d guides the lights emitted from the light sources 14a, 14b, and 14c into the optical engine 32. Then, the lights are modulated by the optical engine 32 and projected by the camera lens 34, for example, to a screen. The power supply module 36 is disposed between the heat-dissipation device 18 and the fan 26; the power supply module 40 is disposed between the optical engine 32 and the fan 28. The power supply modules 36 and 40 are used to provide and control the power needed for operating the entire electronic apparatus (the projector 1).

In addition, according to the embodiment, the projector 1 directly uses LED as the color light source, and the prism can be used as the optical coupling device 14d, wherein the light source 14a is a red-light LED light source, the light source 14b is a green-light LED light source, and the light source 14c is a blue-light LED light source. Because the light emitting efficiency of the red-light LED is more sensitive to temperature, therefore, the red-light LED is connected to the heat-dissipation device 16, so that it can gain benefit by exchanging heat with the air-flow F1 at low-temperature. Furthermore, the projector 1 also includes the heat-dissipation device 30 (marked by a dotted-line frame) disposed between the fan 24 and the heat-dissipation device 20, and the heat-dissipation device 30 is connected to the light source 14a (as shown in FIG. 1, connected by a heat pipe 31 guiding way). Similarly, the heat-dissipation device 30 can gain benefit by exchanging heat with the air-flow F2 at low-temperature, therefore, the light source 14a (the red-light LED light source) can reach better heat-dissipation effect to further control the operation temperature and light emitting efficiency well. It should be further mentioned that the purpose of using the light source 14a as the red-light LED light source in this embodiment is to provide better heat-dissipation conditions for the red-light LED light source, the invention is not limited by this case.

From the mentions above, it can be found that the air-flow F1 in order enters into the casing 12 from the air-inlet 124a, passes through the heat-dissipation device 16, pressed by fan 22, passes through the heat-dissipation device 18 and the power supply module 36, at last, the air-flow F1 is pressed by the fan 26 to pass through the air-outlet 124b to be out of the casing 12. Therefore, the heat generated by all electronic devices disposed on the passage W1 can be dissipated. On the other hand, the air-flow F2 is in order pressed by the fan 24 and enters into the casing 12 from the air-inlet 126a, passes through the heat-dissipation devices 30 and 20, the driving module 38, and the optical coupling module 14d, and then passes through the optical engine 32 and the power supply module 40, at last, the air-flow F2 is pressed by the fan 28 to pass through the air-outlet 126b to be out of the casing 12. Therefore, the heat generated by the electronic devices disposed on the passage W2 can be also dissipated. It should be further mentioned that the optical coupling device 14d and the camera lens 34 are not direct heat sources, only when the optical coupling device 14d and the camera lens 34 are penetrated by the lights for a long period of time, the optical coupling device 14d and the camera lens 34 will absorb a lot of heat, therefore, the heat-dissipation requirements will be generated. In this embodiment, the optical coupling device 14d is disposed on the passage W2, therefore, the heat generated by the optical coupling device 14d can be dissipated by the air-flow F2, so that the optical coupling effect will not be affected by thermal deformation. The camera lens 34 is partially disposed on the passage W2, so that its heat can be dissipated by the air-flow F2. In prior art, less attention is paid for the heat-dissipation of the camera lens in the design of the conventional projector, so that the surface curvature of the camera lens will be changed due to overheat, and the projection effect will be affected.

In addition, in this embodiment, the fan 22 is disposed on an open space between the heat-dissipation devices 16 and 18 (i.e., the position of the fan 22). The open space is adjacent to the light source 14b, therefore, when the projector 1 is assembled; the user can assemble the light source 14b through this open space before the fan 22 is assembled. With that, the inner space of the entire projector 1 used for assembling will be largely reduced to shrink the entire volume of the projector 1. On the other hand, when the light source 14b is required to be dissembled, the fan 22 should be dissembled at first, so that this open space will be available for the user to dissemble the light source 14b through this open space.

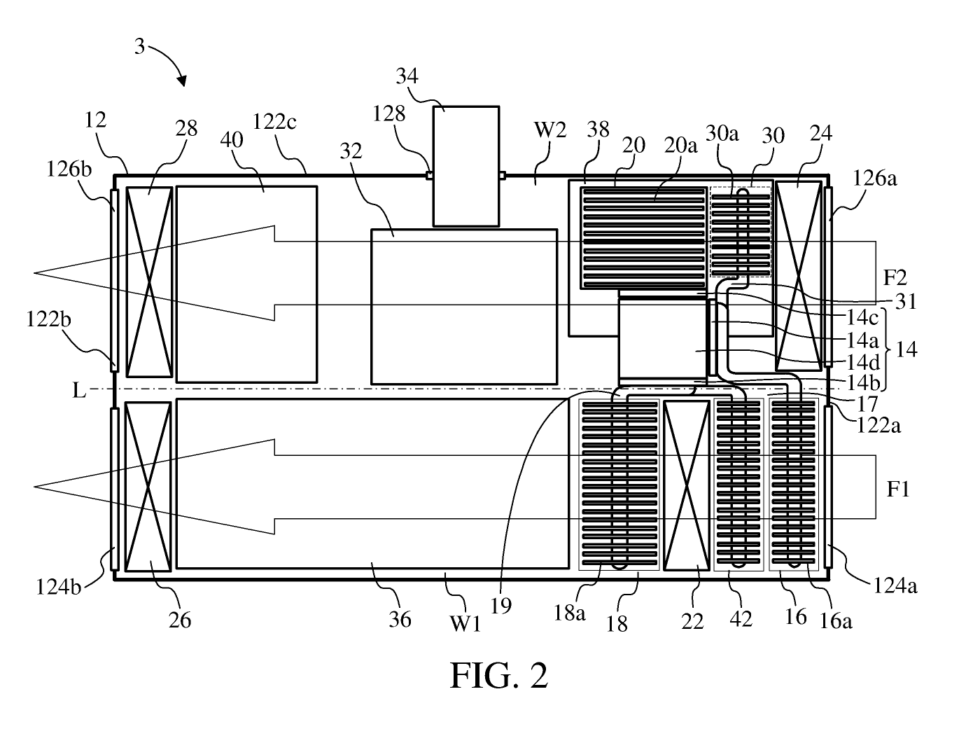

Please refer to FIG. 2. FIG. 2 illustrates a schematic diagram of an electronic apparatus in another embodiment of the invention. Similarly, a projector 3 is used as an example of the electronic apparatus in FIG. 2. The projector 3 of FIG. 2 is substantially the same with the projector 1 of FIG. 1, and the difference between the projector 3 of FIG. 2 and the projector 1 of FIG. 1 is that the projector 3 further includes the heat-dissipation device 42 (marked by a dotted-line frame) disposed between the heat-dissipation device 16 and the fan 22, and the light source 14b is connected to the heat-dissipation device 18 and 42 respectively. In this embodiment (or the embodiment shown in FIG. 1), the light source 14b is a green-light LED light source having larger heat generating amount compared to the other light sources 14a and 14c, therefore, larger heat-dissipation area is provided for enough heat-dissipation efficiency. Considering the heat-dissipation requirement for the light source 14a (red-light LED light source) at the same time, the heat-dissipation device 42 is added to be disposed between the heat-dissipation device 16 and the fan 22 to increase the heat-dissipation area of the light source 14b, so that the light source 14a can still have a heat-dissipation medium of the air-flow F1 with relative low temperature. It should be further mentioned that although the above-mentioned embodiments have two passages and three light sources at the same time, the number of the passages and the light sources can be determined according to the practical configuration of the electronic devices in the electronic apparatus. This invention is not limited by the number and the configuration shown in the above-mentioned embodiments.

Above all, the electronic apparatus and the projector of the invention have smooth passages for the air-flows passing smoothly, so that the turbulence of the air-flows can be reduced and the heat-dissipation efficiency will be increased. In the special configuration shown in the above-mentioned prior arts, several independent passages are disposed to cover the entire inner space of the electronic apparatus to dissipate the heat generated by all electronic devices disposed in the electronic apparatus, so that the number of the flow guiding plate disposed will be reduced, and the volume of the entire electronic apparatus can be further reduced, the electronic devices can be densely disposed as shown in the above-mentioned embodiments to meet the design trend of small size and thickness.

Although the present invention has been illustrated and described with reference to the preferred embodiment thereof, it should be understood that it is in no way limited to the details of such embodiment but is capable of numerous modifications within the scope of the appended claims.

What is claimed is:

1. An electronic apparatus, comprising:
a casing comprising a first air-inlet and a first air-outlet, wherein a first passage is formed between the first air-inlet and the first air-outlet;
an optical module disposed in the casing, the optical module having a first light source and a second light source;
a first heat-dissipation device, disposed on the first passage and connected to the first light source;
a second heat-dissipation device, disposed on the first passage and connected to the second light source; and
a first fan, disposed between the first heat-dissipation device and the second heat-dissipation device on the first passage, the first fan generating a first air-flow passing through the first heat-dissipation device and the second heat-dissipation device.

2. The electronic apparatus of claim 1, further comprising a power supply module disposed between the second heat-dissipation device and the first air-outlet.

3. The electronic apparatus of claim 1, wherein the casing further comprises a second air-inlet and a second air-outlet, and a second passage is formed between the second air-inlet and the second air-outlet, the optical module comprises a third light source, the electronic apparatus further comprises:
a third heat-dissipation device disposed on the second passage and connected to the third light source; and
a second fan disposed on the second passage, the second fan generates a second air-flow passing through the third heat-dissipation device,
wherein the first passage and the second passage are substantially parallel.

4. The electronic apparatus of claim 3, wherein the first passage and the second passage are a straight passage respectively, the casing has a first side, a second side, and a third side, the third side is adjacent to the first side and the second side, and a camera lens is disposed on the third side, the first side and the second side are oppositely disposed, the second air-inlet and the second air-outlet are correspondingly disposed at the first side and the second side respectively, the second fan is adjacent to the second air-inlet, the first light source is connected to the first heat-dissipation device in a heat pipe guiding way, the second light source is connected to the second heat-dissipation device in the heat pipe guiding way, the third light source is connected to the third heat-dissipation device in the heat pipe guiding way, the first heat-dissipation device, the second heat-dissipation device, and the third heat-dissipation device respectively comprise a plurality of fins, length directions of the plurality of fins are substantially parallel to the directions of the first air-flow and the second air-flow.

5. The electronic apparatus of claim 3, further comprising a third fan disposed in the casing and adjacent to the second air-outlet, wherein the third fan and the second fan guide the second air-flow together.

6. The electronic apparatus of claim 3, further comprising an optical engine and a driving module, wherein the optical engine is disposed between the third heat-dissipation device and the second air-outlet, the driving module is disposed beyond the third heat-dissipation device or below the third heat-dissipation device.

7. The electronic apparatus of claim 3, further comprising a fourth heat-dissipation device disposed between the second fan and the third heat-dissipation device, wherein the first light source is connected to the first heat-dissipation device and the fourth heat-dissipation device respectively.

8. The electronic apparatus of claim 3, further comprising a fifth heat-dissipation device disposed between the first fan and the first heat-dissipation device, wherein the second light source is connected to the second heat-dissipation device and the fifth heat-dissipation device respectively.

9. The electronic apparatus of claim 1, further comprising a fourth fan, wherein the fourth fan and the first fan guide the first air-flow together, the first air-flow passes through the first heat-dissipation device, the first fan, the second heat-dissipation device, and the fourth fan, the fourth fan is adjacent to the first air-outlet.

10. The electronic apparatus of claim 1, wherein an open space is existed between the first heat-dissipation device and the second heat-dissipation device, the open space corresponds to the second light source and used for containing the first fan, if the first fan is not assembled yet, a user can assemble or disassemble the second light source via the open space.

11. A projector, comprising:
a casing comprising a first air-inlet, a second air-inlet, a first air-outlet, and a second air-outlet, wherein a first passage is formed between the first air-inlet and the first air-outlet, a second passage is formed between the second air-inlet and the second air-outlet;
an optical module disposed in the casing, the optical module having a first light source and a second light source;
a first heat-dissipation device, disposed on the first passage and connected to the first light source;
a second heat-dissipation device, disposed on the second passage and connected to the second light source;
a first fan, disposed on the first passage, the first fan generating a first air-flow passing through the first heat-dissipation device; and
a second fan, disposed on the second passage, the second fan generating a second air-flow passing through the second heat-dissipation device.

12. The projector of claim 11, further comprising a power supply module disposed between the first heat-dissipation device and the first air-outlet.

13. The projector of claim 11, further comprising a third heat-dissipation device, wherein the optical module comprises a third light source, the third heat-dissipation device is disposed on the first passage and connected to the third light source, the first light source is connected to the first heat-dissipation device in a heat pipe guiding way, the second light source is connected to the second heat-dissipation device in the heat pipe guiding way, the third light source is connected to the third heat-dissipation device in the heat pipe guiding way.

14. The projector of claim 13, further comprising a fourth heat-dissipation device, wherein the third light source is connected to the third heat-dissipation device and the fourth heat-dissipation device respectively.

15. The projector of claim 11, further comprising:
a third fan disposed in the casing and adjacent to the second air-outlet, wherein the third fan and the second fan guide the second air-flow together; and
a fourth fan, wherein the fourth fan and the first fan guide the first air-flow together, the first air-flow passes through the third heat-dissipation device, the first fan, the first heat-dissipation device, and the fourth fan, the fourth fan is adjacent to the first air-outlet.

16. The projector of claim 11, further comprising an optical engine and a driving module, wherein the optical engine is disposed between the second heat-dissipation device and the second air-outlet, the driving module is disposed beyond the second heat-dissipation device or below the second heat-dissipation device.

17. A projector, comprising:
a casing comprising a first air-inlet and a first air-outlet, wherein a first passage is formed between the first air-inlet and the first air-outlet;
an optical module disposed on the first passage, the optical module having a first light source;
a first heat-dissipation device, disposed on the first passage and connected to the first light source; and
a first fan, disposed on the first passage, the first fan generating a first air-flow passing through the first heat-dissipation device and the optical module.

18. The projector of claim 17, wherein the casing comprises a second air-inlet and a second air-outlet, and a second passage is formed between the second air-inlet and the second air-outlet, the optical module comprises a second light source, the projector further comprises:
a second heat-dissipation device disposed on the second passage and connected to the second light source; and
a second fan disposed on the second passage, the second fan generates a second air-flow passing through the third heat-dissipation device, wherein the first passage and the second passage are substantially parallel.

19. The projector of claim 18, wherein the optical module comprises a third light source, the projector further comprises a third heat-dissipation device disposed on the second passage and connected to the third light source, wherein the second fan is disposed between the second heat-dissipation device and the first heat-dissipation device.

20. The projector of claim 18, further comprising:
a third fan disposed in the casing and adjacent to the second air-outlet, wherein the third fan and the second fan guide the second air-flow together; and
a fourth fan disposed in the casing and adjacent to the first air-outlet, wherein the fourth fan and the first fan guide the first air-flow together.
